(19) United States
(12) Patent Application Publication
(10) Pub. No.: US 2015/0256916 A1
(43) Pub. Date: Sep. 10, 2015

(54) Programmable Acoustic Device And Method For Programming The Same

(71) Applicant: Knowles Electronics, LLC, Itasca, IL (US)

(72) Inventors: Martin Volk, Willowbrook, IL (US); Nilay Patel, Elk Grove Village, IL (US)

(21) Appl. No.: 14/631,936

(22) Filed: Feb. 26, 2015

Related U.S. Application Data
(60) Provisional application No. 61/947,721, filed on Mar. 4, 2014.

(51) Int. Cl. H04R 1/08; G11C 16/26; H04R 3/04; G11C 16/10

(52) U.S. Cl. CPC H04R 1/08; G11C 16/10; G11C 16/26; H04R 3/04; H04R 2201/003

(57) ABSTRACT

A micro electro mechanical system (MEMS) microphone includes a MEMS device, a flash memory coupled to the MEMS device, and an external port coupled to the flash memory. The external port is configured to be selectively coupled to an external programming device. The external programming device selectively reads first information from the flash memory and writes second information to the flash memory without the use of a one-time fuse.

### CROSS REFERENCE TO RELATED APPLICATION

This patent claims benefit under 35 U.S.C. §119 (e) to U.S. Provisional Application No. 61/947,721 entitled “Programmable Acoustic Device and Method for Programming the Same” filed Mar. 4, 2014, the content of which is incorporated herein by reference in its entirety.

### TECHNICAL FIELD

This application relates to acoustic devices and, more specifically, to the configurations of these devices.

### BACKGROUND OF THE INVENTION

Various types of acoustic devices have been used over the years. One example of an acoustic device is a microphone. Generally speaking, a microphone converts sound waves into an electrical signal. Microphones sometimes include multiple components that include micro-electro-mechanical systems (MEMS) and integrated circuits (e.g., application specific integrated circuits (ASICs)). A MEMS die typically has disposed on it a diaphragm and a back plate. Changes in sound energy move the diaphragm, which changes the capacitance involving the back plate thereby creating an electrical signal. The MEMS dies is typically disposed on a base or substrate along with the ASIC and then both are enclosed by a lid or cover.

The ASICs in these devices typically perform a number of different functions. For example, the ASICs process the signals received from the MEMS die. Other examples of processing functions are possible.

The ASICs typically need to be programmed. In order to accomplish this programming, a programming device needs to be coupled to the microphone. In these regards, an electrical path is created between the exterior of the microphone and the ASIC. The electrical paths typically utilized one-time fuses. A one-time fuse may be a polyfuse that is located in the ASIC. A programmer connects a programming device to the polyfuse and then performs the programming of the ASIC. However, the fuses are used for one time only. In other words, once the fuse is burned by the programmer, the fuse could not be un-burned and, consequently, could not be used for any future programming. Put still another way, in previous devices only a one-time, temporary connection was provided.

The ability to program a microphone only once somewhat limits the utility of these devices since their programming and values cannot change over time. This has created some user dissatisfaction with these previous approaches.

### BRIEF DESCRIPTION OF THE DRAWINGS

For a more complete understanding of the disclosure, reference should be made to the following detailed description and accompanying drawings wherein:

FIG. 1 comprises a block diagram of a system a programmable acoustic device according to various embodiments of the present invention;

FIG. 2 comprises a flowchart for programming (or re-programming) and operating a programmable acoustic device according to various embodiments of the present invention;

FIG. 3, FIG. 4, and FIG. 5 comprise diagrams describing a protocol for programming (or obtaining information from) a programmable acoustic device according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Approaches are described that provide for the fast and efficient programming of memories disposed in or utilized with micro electro mechanical systems (MEMS) microphones. In one aspect, a MEMS microphone includes a flash memory and the flash memory may include trim codes, frequency response, sensitivity, signal conditioning, or other types of information that may be exchanged on-the-fly with a programming device that is coupled to the MEMS microphone. These features allow the MEMS microphone to not only exchange data with the outside world, but be re-programmed on the fly. This, in turn, provides a much more efficient, powerful, and flexible microphones that can have some of its operational parameters change as conditions change.

In some of these embodiments, a flash memory in a MEMS microphone is programmed. In these regards, a programming tool is connected to a MEMS microphone. Information is transmitted from the programming tool to a flash memory device that is disposed within the MEMS microphone. Alternatively, information may be uploaded to the programming tool from the flash memory in the MEMS microphone. The transmission of data is not limited to being performed by a programming tool, but can include various electronics connected to a MEMS microphone that is in circuit. The information may include, for example, include trim codes, frequency response, sensitivity, signal conditioning, or other types of information. The use of one-time fuses is avoided and the resultant microphone becomes a flexible device that can have its operating parameters changed on-the-fly. It will be appreciated that any information that is written to the flash memory can be read out. This information can include data for, but is not limited to sensitivity, trim code, frequency response, signal conditioning, and so forth. The flash memory can be a random access memory, read only memory, NAND based memory, or other types of memory.

The flash memory can be written/programmed to or read from after the MEMS microphone has been installed in a final product (e.g., a cellular phone, tablet, or laptop). In other words, the programming device or programming tool is not limited to a special device external to the final product, but the final product (e.g., cellular phone, tablet, or laptop) that the microphone is disposed in can also be used as a programming device.

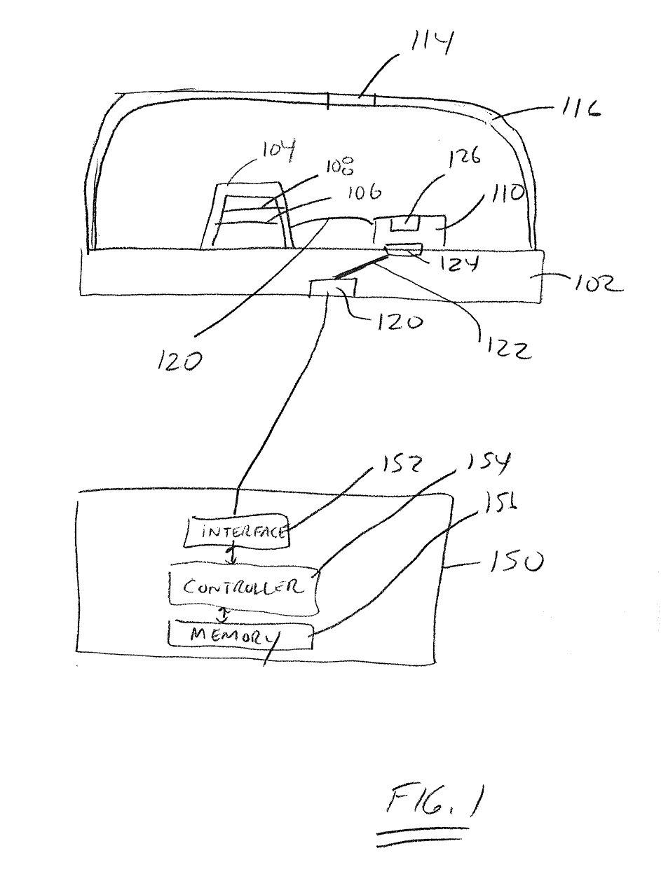

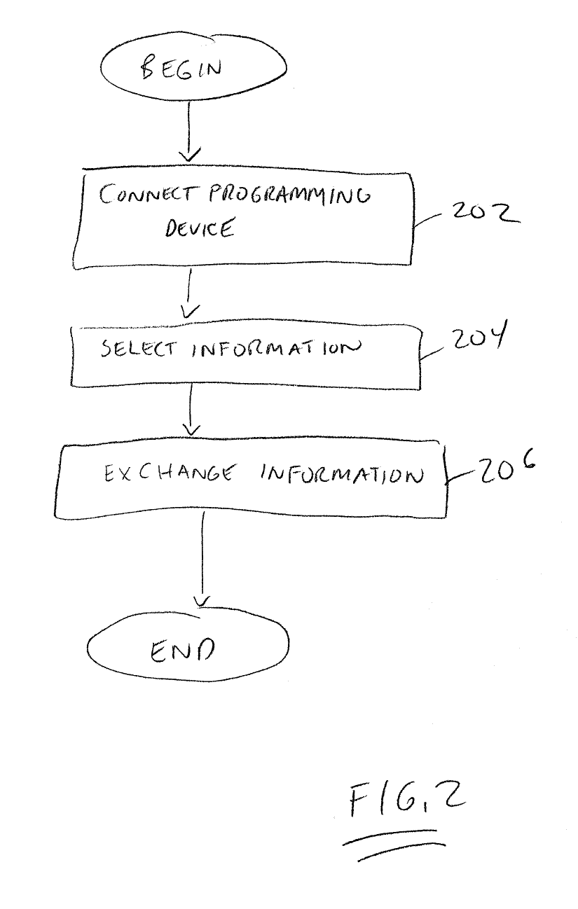

Referring now to FIG. 1, one example of a MEMS microphone 100 that can be programmed and/or re-programmed on-the-fly is described. The MEMS microphone 100 includes a substrate 102, a MEMS die 104 (including a diaphragm 106 and a back plate 108), an application specific integrated circuit (ASIC) 110 (including a flash memory 126), and a port 114. A cover 116 encloses the MEMS die 104 and the ASIC 110. Although the microphone 100 shown here is a top port device (the port 114 extends though the cover 116), it will be understood that the microphone 100 could also be a bottom port device (with the port 114 extending through the base 102).

In operation, the diaphragm 106 moves as sound pressure enters through the port 114. This action causes a changing electrical potential to be created with respect to the back plate 108, thereby creating an electrical signal (current or voltage). This electrical signal is communicated to the ASIC 110 over wires 118.

A pad 120 is formed on the outer edge of the substrate 102. Internal wires, conductive traces, or conductive conduits 122 couple the pad 120 to an internal connector 124. The internal connector 124 couples to an appropriate pin of the ASIC 110. In one aspect, this is the programming pin of the ASIC 110. The programming pin electrically couples to a flash memory 126 in the ASIC 110. It will be appreciated that in this example the flash memory 126 is located in the ASIC. In other aspects, the flash memory can be located external to the ASIC 110 and the internal connector 124 can connect directly to the flash memory 126. The flash memory 126 is any type of memory that can quickly receive information (be programmed) or transmit information (be read), and hold information until reprogrammed or erased. In these regards, the flash memory 126 can be any suitable device known to those skilled in the art.

It will also be understood that the internal wires, conductive traces, or conductive conduits 122 may be multiple wires or electrical connectors or a single wire or electrical connector. In the former case (i.e., multiple wires), the pad 120 and the internal connector 124 may be multiple connections or conductors.

A programming device 150 couples to the pad 120. Consequently, a continuous, unbroken, a permanent electrical path is formed between the programming device 150 and the flash memory in the ASIC 110. The programming device includes an interface 152, a controller 154, and a memory 156. The memory 156 may include parameters 158, which may be programmed into the flash memory 126 or received from the flash memory 126. The parameters 158 may include any type of parameter that is used by a MEMS microphone or the parameters may be software code, instructions, or software for downloading into the flash memory 126.

The controller 154 is any type of processing device such as a microprocessor. The interface 152 provides communicative coupling between the programming device 150 and the microphone 100. The interface 152 may be implemented in any combination of hardware or software. The memory 156 is any type of memory storage device such as a random access memory or a read only memory. Other examples of memory are possible.

The programming device 150 may also have a screen and keypad (not shown in FIG. 1). The screen can be used to present information obtained from the flash memory 126 to a user. A key pad may be used to enter information that a user desires to upload to the flash memory 126.

Additionally, the programming device 150 may itself couple to other networks or devices. For example, it may couple to the Internet and may obtain new information from the Internet by which to program the flash memory 126. In addition, the information obtained from the flash memory 126 may be sent to other devices such as other personal computers, lap tops, cellular phones, or personal digital assistants. Other examples are possible.

In one example of the operation of the system of FIG. 1, information is transmitted from the MEMS microphone 100 to the flash memory device 126 that is disposed within the MEMS microphone 100. Alternatively, information may be uploaded from the flash memory 126 in the MEMS microphone 100. The information may include, for example, include trim codes, frequency responses, sensitivity, signal conditioning, or other types of information. The use of one-time fuses is avoided and the resultant microphone becomes a flexible device that can have its operating parameters changed on-the-fly.

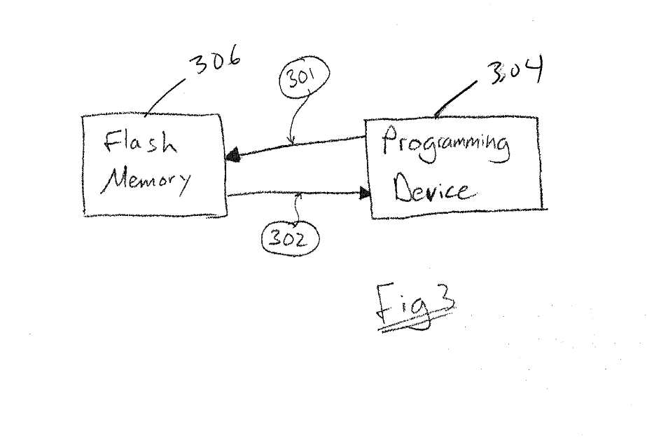

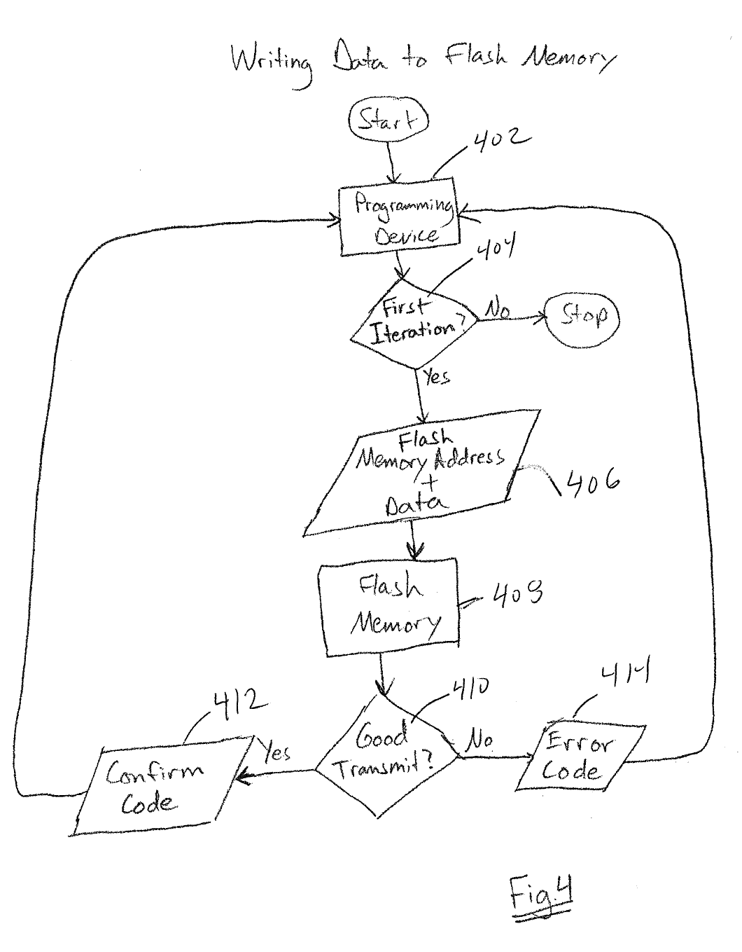

Referring now to FIG. 2, one example of an approach for programming and re-programming a flash memory in a MEMS microphone (or other acoustic device) is described. At step 202, a programming device is connected to a MEMS microphone. The connection can be accomplished by connecting a programming lead wire (or wires) to a programming pad on the base of the microphone.

At step 204, a user at the programming device selects information to send to the flash memory. Alternatively (or in addition), the user may select information to be obtained from the flash memory.

At step 206, the information that is desired to program the flash memory is sent to the flash memory from the programming device. In addition (or alternatively), any requested information is read from the flash memory.

It will be appreciated that these steps may be performed at initial manufacturing. In addition, the steps may be performed after initial manufacturing/initial programming is complete to change any operational parameter (or any software programming) of the microphone. Consequently, a MEMS microphone is provided whereby its operation can be changed on-the-fly.

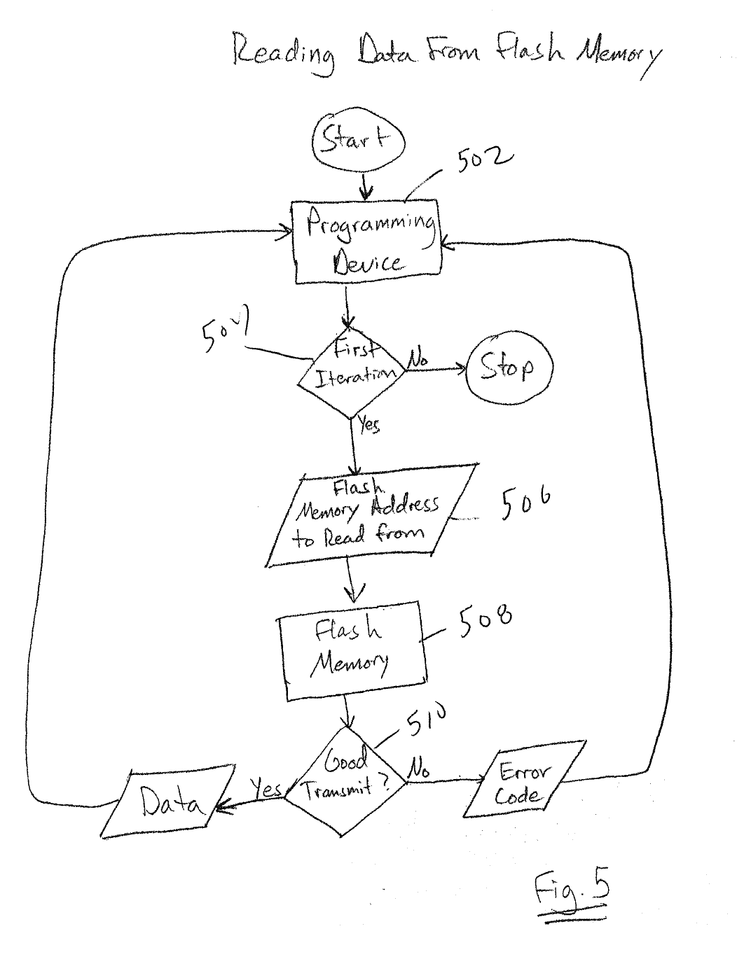

Referring now to FIG. 3, a programming device 304 (e.g., the programming device 150 from FIG. 1) is shown with the interface to a flash memory 306 (e.g., the flash memory 126 from FIG. 1). The transmission line for data from the programming device to the flash memory is represented by the element labeled 301. The receive line for data from the flash memory to the programming device is represented by the element labeled 302. In one aspect, lines 301 and 302 can consist of any combination of elements 120, 122, and 124 in FIG. 1.

Referring now to FIG. 4, the protocol for storing of data is described. At step 402, the programming device initiates the programming event, and it is determined if this is the first iteration at step 404. If this is not the first iteration, execution ends. If it is the first iteration, at step 406 the flash memory address and data are transmitted to the flash memory. The address specifies where in the flash memory the programming or read event is performed which occurs at step 408. At step 410, it is determined whether the transmission was a good transmission. Depending on good communication with the programming device, the flash memory will send back a confirmation code 412 or an error code 414 after the programming is complete. Furthermore, not shown in the diagram, an error code can also be transmitted at any point in the flow diagram where an error occurs. Good communication refers to the correct data being transmitted between the programming device and flash memory. Of course if no communication exists, no code or data will be sent back.

Referring now to FIG. 5, the protocol for obtaining information from the flash memory is shown. At step 502, the programming device initiates the read event. It is determined if this is the first iteration at step 504. If this is not the first iteration, execution ends. If it is the first iteration, the flash memory address 506 to read from is sent to the flash memory at step 508. At step 510, it is determined whether the transmission was a good transmission. Depending on good communication with the programming device, the flash memory will send back the respective data 512 or an error code 514 for bad communication. Furthermore, not shown in the diagram, an error code can also be transmitted at any point in the flow diagram where an error occurs. There are industry standards that can be used for checking if correct data is transmitted such as cyclic redundancy checks that can be sent as a part of the data.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A micro electro mechanical system (MEMS) microphone, comprising:
a MEMS device;
a flash memory coupled to the MEMS device;
an external port coupled to the flash memory, the external port configured to be selectively coupled to an external programming device, the external programming device selectively reading first information from the flash memory and writing second information to the flash memory without the use of a one-time fuse.

2. The microphone of claim 1, wherein the second type of information comprises programming code.

3. The microphone of claim 1, wherein the first type of information comprises trim codes or frequency responses.

4. The microphone of claim 1, wherein the programming device is coupled to other networks.

5. A method of interfacing with a flash memory device disposed at a micro electro mechanical system (MEMS) microphone, the method comprising:
attaching a programming device to the MEMS microphone;
selectively reading first information from the flash memory or writing second information to the flash memory in the microphone such that no one-time fused is used and the reading or writing is repeatable.

6. The method of claim 5, wherein the second type of information comprises programming code.

7. The method of claim 5, wherein the first type of information comprises trim codes or frequency responses.

8. The method of claim 5, wherein the programming device is coupled to other networks.
